(19) United States
(12) Patent Application Publication
(10) Pub. No.: US 2024/0369653 A1
(43) Pub. Date: Nov. 7, 2024

(54) HYPERPOLARISATION METHOD AND APPARATUS

(71) Applicant: CAMBRIDGE ENTERPRISE LIMITED, Cambridge, Cambridgeshire (GB)

(72) Inventors: Arnaud COMMENT, Cambridge (GB); Adam GAUNT, Cambridge (GB)

(21) Appl. No.: 18/684,000

(22) PCT Filed: Aug. 16, 2022
(86) PCT No.: PCT/GB2022/052130

§ 371 Date: Feb. 15, 2024

(30) Foreign Application Priority Data
Aug. 16, 2021 (GB) 2111735.3

(51) Int. Cl. G01R 33/28; G01N 1/28; G01N 1/42; G01N 1/44; G01R 33/30

(52) U.S. Cl. CPC G01R 33/282; G01N 1/2813; G01N 1/42; G01N 1/44; G01R 33/30

(57) ABSTRACT

In a method for preparing a hyperpolarised sample, for example for carrying out a magnetic resonance technique, the sample is formed as a frozen layer (4) of a starting solution on a surface of a thermoconductive sample holder (1,2). The solution comprises molecules for hyperpolarisation, and photo-reactive molecules. Free radicals are induced in the frozen layer by exposing it to radiation. The sample is then hyperpolarised by dynamic nuclear polarization at a dynamic nuclear polarization temperature. After hyperpolarisation, the temperature of the sample is raised to a thermalisation or quenching temperature by thermal conduction of heat through the sample holder, to quench the free radicals. The polarised sample may then be stored for use, retaining its polarisation.

The invention relates to a method and an apparatus for preparing a hyperpolarised sample, or solution, for example for use in magnetic resonance techniques.

The project leading to this application has received funding from the European Research Council (ERC) under the European Union's Horizon 2020 research and innovation programme (grant agreement No 682574).

### BACKGROUND

Hyperpolarisation of a molecule, termed a molecule of interest, dramatically increases the nuclear magnetic resonance (NMR) signal when samples or solutions containing the molecule are used in magnetic resonance (MR) techniques. Hyperpolarisation preferentially orients the nuclear spins of the molecule of interest prior to its introduction or injection into (depending on the MR technique being used) for example a tube, a bioreactor, an animal, or a human being.

Hyperpolarisation can most effectively be achieved by Dynamic Nuclear Polarisation (DNP), in which a concentration of about 10-100 mM of free radicals is added to a solution containing the molecules of interest. The solution is then introduced into a polariser operating at a temperature below 2 K and a magnetic field of 3.35-10.1 T. Microwaves with a frequency close to the electron spin resonance (ESR) of the free radicals are delivered to the frozen solution while inside the low-temperature and high-magnetic field environment.

One option is to add stable free radicals to the solution containing the molecules of interest. After DNP, the frozen solution is then rapidly dissolved with hot solvent, typically water, to obtain a liquid-state solution containing the hyperpolarised molecules. This dissolution step needs to be performed within the high magnetic field environment of the polariser to maintain the high polarisation of the nuclear spins through the solid-to-liquid phase transformation. Before injection into humans, for example in a hospital, the free radicals must then be filtered out of the solution and their residual concentration measured in a quality control (QC) procedure to be below an acceptable biocompatible level.

Another option is to add a photo-reactive species to the solution containing the molecules of interest. The photo-reactive species generates free radicals upon photo-irradiation with light in the ultraviolet and/or visible (UV-Vis) spectrum at cryogenic temperature, typically below 200 K. DNP is then carried out in a polariser operating, as above, at a temperature below 2 K and a magnetic field of 3.35-10.1 T. After DNP the frozen solution is warmed to a temperature above 200 K at which the free radicals are quenched. This thermalisation process therefore removes the need for dissolution inside the polariser and provides an opportunity to extract the hyperpolarised frozen solution from the polariser in its solid state without losing its enhanced nuclear polarisation. In addition, replacing stable free radicals by non-persistent photo-induced free radicals can circumvent the need for filtration before the sample is injected into a human or animal.

Optimising this DNP method requires particularly accurate control of the temperature of the sample for each of the stages in the method, namely photo-irradiation, hyperpolarisation, thermalisation, and subsequent storage.

Patent publication US20190094316 describes a system for carrying out this DNP process. The substance for hyperpolarisation is formed into frozen packets, each packet consisting of a discrete frozen amount of the substance, or solution, containing the molecule of interest and a photo-reactive species. The frozen packets may be of spherical bead shape, for example. Each packet is transportable, carried by one or more fluid media such as liquid nitrogen, gaseous helium and liquid helium, through apparatus for sequentially exposing the packet to radiation to form free radicals, hyperpolarising the molecules of interest, thermalising the packet, and then storing the packet for later use. At each stage, the temperature of the packet is controlled by direct cooling or warming, by the temperature of the fluid with which the packet is in contact.

A different approach to hyperpolarisation, termed “brute-force polarisation”, involves introducing molecules of interest, with no free radicals, into a liquid helium cryostat inside a superconducting magnet and waiting for the spin polarisation to passively build up through spin-lattice relaxation. The publication “Brute-Force Hyperpolarization for NMR and MRI”, by Hirsch et al., J. Am. Chem. Soc. 2015, 137, 8428-8434, describes this approach and illustrates the use of a shuttle for supporting the sample. The shuttle is a hollow cylindrical tube of polycarbonate, and the sample is frozen onto its radially inner surface. The shuttle, carrying the sample, is carried by fluids through the hyperpolarisation process in a similar way to the sample packets described above, and the sample temperature is determined by contact between the sample and those fluids. The shuttle is used to support the sample because brute-force polarisation requires very rapid movement of the sample into and out of the cryostat, which can damage samples in the form of frozen packets. The shuttle would not be suitable for DNP, for example because it would block exposure of the sample to UV-Vis radiation for generating photo-induced free radicals.

For brute-force polarisation to be effective and reach polarisation above a few percents, ultra-low temperatures (below 500 mK) must be reached, rendering it both technologically difficult and impractical. As noted in the publication above, hyperpolarisation using DNP has achieved polarisation levels 100 times higher than achieved by brute force polarisation.

In any DNP process the temperature control of the solution, or sample, needs to be accurate, rapid and consistent. Conventionally, temperature control is performed by contacting the hyperpolarisation sample with a flow of a fluid at a desired temperature, such as liquid nitrogen or gaseous or liquid helium, or hot water for the dissolution process. This direct cooling or warming is a convenient way to control the temperature of the sample, because the fluids are available and are being used to control the temperatures of the various pieces of apparatus used in the DNP method. However, it is inherently difficult to control the amount of heat transfer, and hence the temperature of the sample, using direct contact with a gas or a liquid. In practice this leads to problems such as incomplete quenching of the radicals or partial melting of the sample during thermalisation, both resulting in polarization loss.

### SUMMARY OF INVENTION

The invention provides a method and an apparatus for preparing a hyperpolarised sample, and a storage method and a storage vessel for storing and/or transporting a hyperpolarised sample, as defined in the appended independent claims to which reference should now be made. Preferred or advantageous features of the invention are set out in dependent subclaims.

In a first aspect, the invention may thus provide a method for preparing a hyperpolarised sample in which the sample is formed as a frozen layer of a solution, containing molecules of interest for hyperpolarisation and a photo-reactive species, on a surface of a thermoconductive sample holder. The molecules of interest and the photo-reactive species may be different molecules or they may be the same molecule, if the molecule of interest is itself photo-reactive to generate free radicals. After photo-irradiation of the sample to generate free radicals and after dynamic nuclear polarisation (DNP), the temperature of the hyperpolarised sample may be raised by thermal conduction through the thermoconductive sample holder, to a thermalisation temperature at which the free radicals are quenched. This may be termed thermal annihilation of the free radicals. The hyperpolarised sample may then be stored, or used, as required.

In the prior art, the temperature of the sample is conventionally controlled by direct contact between the sample and a fluid at the desired temperature, such as liquid nitrogen, or gaseous or liquid helium. By contrast, in embodiments of the invention, the temperature of the sample can be controlled by conduction of heat through the thermally-conductive sample holder as described in more detail below. This may advantageously allow more direct, rapid and consistent control of the sample temperature, as well as offering convenient positioning of the sample on the support.

The fact that the sample is frozen on a sample holder that can be maintained in a specific position also prevents uncontrolled motion of the sample during the thermalisation process. For example in prior-art methods the sample may be able to move or tumble around when a fluid is used for thermalisation. This can break frozen samples into smaller parts, preventing tight control of the temperature across the sample. Preparing and hyperpolarising a sample is complex and expensive, and so reducing the occurrence of any failures in the process is particularly important.

The temperature of the sample must be controlled throughout the process of preparing a hyperpolarised sample for use, but it is particularly important to control the temperature rise for thermalisation after DNP, as this step quenches the free radicals and by reducing the free-radical concentration as low as possible enables effective storage of the sample while retaining its polarisation. The temperature during DNP is typically below 2K, and the thermalisation temperature is typically between 200K and 273K. It is important to raise the temperature of the sample rapidly and accurately between these temperatures in order to optimise the thermalisation. It is also crucial for the temperature to be homogenous throughout the sample and to avoid raising the temperature of any part of the sample above the melting point of the sample, which can for instance be as low as 250K in a aqueous solution containing one third ethanol. In embodiments of the invention, this temperature rise is therefore implemented by thermal conduction of heat through the thermoconductive sample holder into the frozen layer of the sample.

In order to control the temperature of the sample by conduction, the sample is preferably in good thermal contact with the sample holder, and the thickness of the sample is preferably small. Preferably, therefore, the sample is in the form of a layer on a surface of the sample holder, of thickness preferably less than 5 mm, or 3 mm, or 2 mm or 1 mm.

Heat conduction through the sample holder is advantageously rapid. Heat conduction through the sample itself may be slower and therefore the form of the sample, in a thin layer on the sample holder, may advantageously ensure that the temperature of the entire volume of the sample is accurately controlled, and can be rapidly changed.

In embodiments of the invention, other temperature changes during the hyperpolarisation process may be implemented by thermal conduction through the thermoconductive sample holder, or they may be implemented by contact between the sample and a fluid (or cryogen), or by a combination of these two methods.

For example, in order to secure the sample to the sample holder, the temperature of the sample holder may be reduced below the freezing point of the sample. The temperature of the sample may then be reduced to a photo-irradiation temperature at which free radicals can be photo-induced in the frozen layer by exposing it to UV-Vis light, and then to a dynamic nuclear polarization temperature, so that dynamic nuclear polarization of the sample can be performed to hyperpolarise the sample. All of these temperature changes may be implemented by thermal conduction through the sample holder, or by contacting the sample with a fluid, or by a combination of these techniques.

After thermalisation, the hyperpolarised sample may then be cooled, optionally by thermal conduction through the sample holder, for storage or transport. Advantageously the sample can conveniently be held on the sample holder during storage and/or transport.

After storage and/or transport of the sample, the temperature of the hyperpolarised sample may advantageously be raised, either again by thermal conduction through the sample holder or by direct contact with a fluid, to melt the sample, for example for use in a magnetic resonance method. This may conveniently allow a hyperpolarised sample to be conveniently stored and transported in a frozen state, for example from a facility where DNP is performed to a place, such as a hospital, where a magnetic resonance procedure is to be carried out. The sample may then be melted for use.

In a preferred embodiment, the thermoconductive sample holder comprises a heat exchanger, and the temperature of the sample is controlled by conduction of heat through the heat exchanger. The sample holder may comprise a sample support, or a sample support surface, and a heat exchanger. The sample support and the heat exchanger are preferably in good thermal contact with each other. The sample support and the heat exchanger may be separate components, coupled together for use either separably or non-separably. The sample support and the heat exchanger may be portions of the same component. For example, they may be suitably shaped or fabricated portions of a single component. They may be made of the same or different materials.

The heat exchanger may be cooled or heated by contacting it with a fluid flow of liquid or gas at a predetermined temperature. Alternatively, or in addition, the heat exchanger may be cooled or heated by thermal contact with an electrical cooler or an electrical heater. The good thermal contact between the sample support and the heat exchanger then leads to rapid heat flow to or from the sample on the sample support.

It is important that the temperature of the sample is known, and so in a preferred embodiment the temperature of the sample holder is monitored or measured by means of a thermometer, such as an electrical thermometer or thermocouple.

When thermalisation is performed, the sample is typically withdrawn or partially withdrawn from the polariser, and so the ambient temperature and the temperature of any fluid (liquid or gas) around the sample may change. Similarly, in other steps in the process for preparing the polarised sample, the temperature of the ambient surroundings of the sample may change, particularly as the sample is moved. Consequently, at these times some ambient heat may flow between the surrounding fluid and the sample. However, in embodiments of the invention where the temperature of the sample is changed and controlled by heat conduction through the sample holder, more than 70%, and preferably more than 80% or 90%, of the heat flowing to or from the sample is by conduction through the sample holder. The proportion of the heat flowing to or from the sample by conduction through the sample holder is sufficient to enable the control of that heat conduction to control the temperature of the sample as required for the sample preparation process.

In circumstances as described above where the temperature of the sample may be changed by a combination of thermal conduction through the sample holder and by contacting the sample with a fluid, comparable amounts of heat may flow to or from the sample by each mechanism (for example in a ratio between about 60:40 and 40:60, or between about 55:45 and 45:55). However, control of the heat flowing by conduction is still preferably enough to enable control of the temperature of the sample, at least at the end of any sample temperature change in the process of preparing the polarised sample.

In order to protect the sample, a cap may be positioned over the frozen sample and the thermoconductive sample holder, preferably prior to the dynamic nuclear polarization. The cap may be designed to serve as a reservoir for collecting the sample when it is melted for use. Preferably, the cap may be transparent to UV-Vis light. This may allow UV-Vis light to reach the frozen sample through the cap, which is particularly important if the cap is positioned over the frozen sample prior to dynamic nuclear polarization of the frozen sample.

At least a portion of the cap may comprise a porous wall. The cap may comprise one or more porous walls. In some embodiments, all of the walls of the cap may be porous. The porous wall may be configured to allow cryogens, in particular helium, to pass through. The porous wall may be permeable to cryogens such as helium. Preferably, the porous wall does not allow liquid sample to pass through. Preferably, the porous wall is not permeable to liquid sample. The porous wall preferably comprises pores with a pore size of 0.2 micron or less.

As noted above, the starting solution comprises a molecule of interest and a photo-reactive compound. The photo-reactive compound may be a keto-acid. Alternatively, the molecule of interest may be photo-reactive, for example pyruvic acid. This form of DNP process, in which the free radicals are quenched by thermalisation so that the sample can be retained in a frozen state until it is melted for use in a magnetic resonance procedure, is particularly suited to the method of the invention. In a preferred embodiment, the solid sample can conveniently be retained on the same sample holder, preferably with its temperature being monitored continuously, during the entire process from photo-irradiation to form the free radicals, until the hyperpolarised sample is melted for use.

The molecule of interest may be any molecule observable using NMR spectroscopy. For example the molecule of interest may be any molecule containing at least one NMR active nucleus.

In a preferred implementation of the invention the dynamic nuclear polarisation may be carried out in a polariser, and the method may further comprise the steps of withdrawing the hyperpolarised sample and the thermoconductive sample holder from the polariser, and placing them in a storage or transport vessel, or apparatus, comprising a cooler couplable to the thermoconductive sample holder to maintain the sample at a predetermined storage temperature, and a magnetic field generator for holding the sample within a magnetic field, until the sample is to be melted and used. The magnetic field generator is preferably a permanent magnet. An electromagnet, optionally battery-powered, might be used but may disadvantageously generate unwanted electrical heat in the storage vessel.

In a further aspect, the invention may advantageously provide an apparatus for handling a hyperpolarised sample, comprising a thermoconductive sample holder having a support surface for, in use, carrying the sample in the form of a frozen layer, thermally couplable for the conduction of heat to and from a source of heat for controlling the temperature of the sample.

The thermally conductive sample holder may be thermally coupleable for the conduction of heat to and from a source of heat for controlling the temperature of the sample between a dynamic nuclear polarization temperature and a thermalisation or quenching temperature.

Advantageously, the sample holder apparatus comprises a heat exchanger for coupling the thermoconductive sample holder to the source of heat. The source of heat may comprise a gas or liquid at a predetermined temperature, and preferably a flow of gas or liquid at the predetermined temperature. Alternatively, or in addition, the source of heat may comprise an electrical cooler or an electrical heater.

In a preferred embodiment, a thermometer is coupled to the sample holder. The thermometer may for example be an electrical thermometer or thermocouple for measuring or monitoring the temperature of the sample holder. The thermometer may be coupled to the sample support or the heat exchanger or both. Feedback control from the thermometer to the cooling system using a suitable controller may be used to maintain and control the temperature of the sample.

The apparatus may further comprise a cap positionable over the frozen sample and the thermoconductive sample holder. When the hyperpolarised sample is required for use, the sample holder may be oriented so that the cap is positioned below the sample, and heat may be applied to the thermoconductive sample holder so that the sample can conveniently be melted and collected in the cap.

Preferably, the cap may be transparent to UV-Vis light. This may allow UV-Vis light to reach the frozen sample through the cap, which is particularly important if the cap is positioned over the frozen sample prior to dynamic nuclear polarization of the frozen sample.

At least a portion of the cap may comprise a porous wall. The cap may comprise one or more porous walls. In some embodiments, all of the walls of the cap may be porous. The porous wall may be configured to allow cryogens, in particular helium, to pass through. The porous wall may be permeable to cryogens such as helium. Preferably, the porous wall does not allow liquid sample to pass through. Preferably, the porous wall is not permeable to liquid sample. The porous wall preferably comprises pores with a pore size of 0.2 micron or less.

In a preferred embodiment of the invention, the sample holder carrying the sample is conveniently compatible with one or more of the items of equipment required to prepare the hyperpolarised sample. Thus, the sample holder may be positionable for exposure of the sample, in use, to radiation to form free radicals in the sample. It may also be insertable into a polariser for dynamic nuclear polarisation of the sample, and withdrawable from the polariser.

After the sample has undergone dynamic nuclear polarisation the sample holder may then be couplable to a suitable temperature source for thermalisation and then engageable with a storage apparatus in which the sample holder can be coupled to a cooler and the sample held in a magnetic field. Depending on the materials and the process parameters involved, this may advantageously enable storage of the hyperpolarised sample for a significant length of time, for example of up to 24 or 48 hours, without losing its polarization. For example, in preferred embodiments of the invention, this long storage time is enabled by the effective quenching of the free radicals, due to accurate temperature control of the sample during thermalisation.

In a further aspect, the invention may also provide a storage apparatus, or transport apparatus, for receiving the sample holder as described herein. The storage apparatus may comprise a cooling apparatus thermally couplable to the thermoconductive sample holder and a magnetic field generator for applying a magnetic field to a frozen sample held, in use, by the sample holder. Depending on the materials and the process parameters involved, the hyperpolarised sample may be stored in the storage or transport apparatus for a significant length of time, of up to 24 or 48 hours, without losing its polarization.

During storage, the sample holder may be thermally coupled to a cryocooler to maintain the desired temperature of the sample, or the sample holder or the sample may be in contact with a suitable fluid or cryogen, such as liquid neon.

### DESCRIPTION OF SPECIFIC EMBODIMENTS OF THE INVENTION

Specific embodiments of the invention will now be described by way of example, with reference to the following drawings, in which:

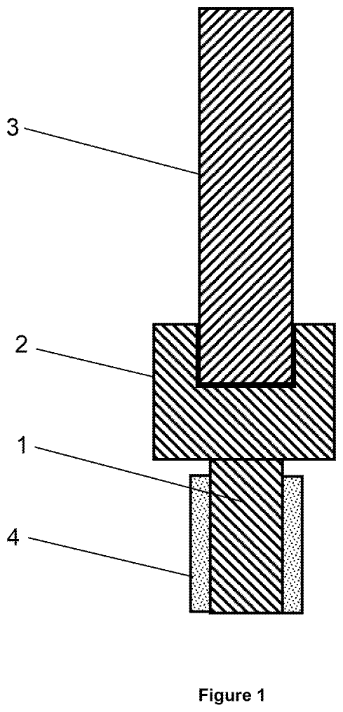

FIG. 1 is a cross section of a thermoconductive sample holder according to a first embodiment of the invention;

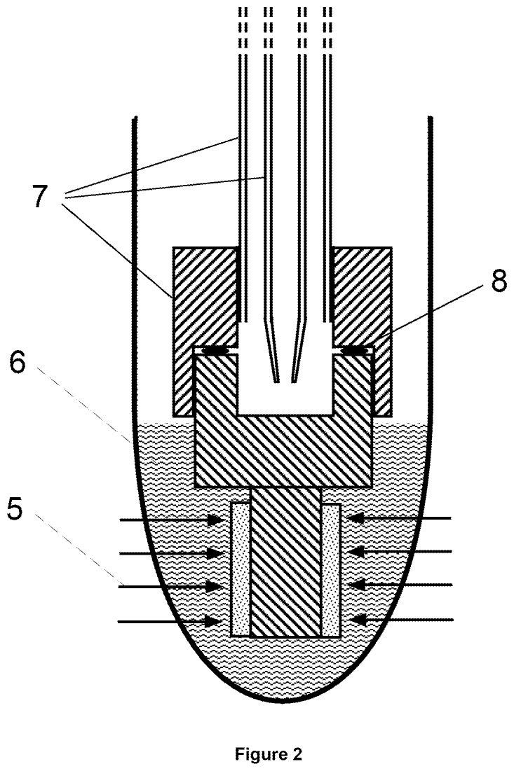

FIG. 2 illustrates the photo-generation of non-persistent free radicals inside a frozen thin layer of a starting solution, using a fluid heater assembly embodying the invention;

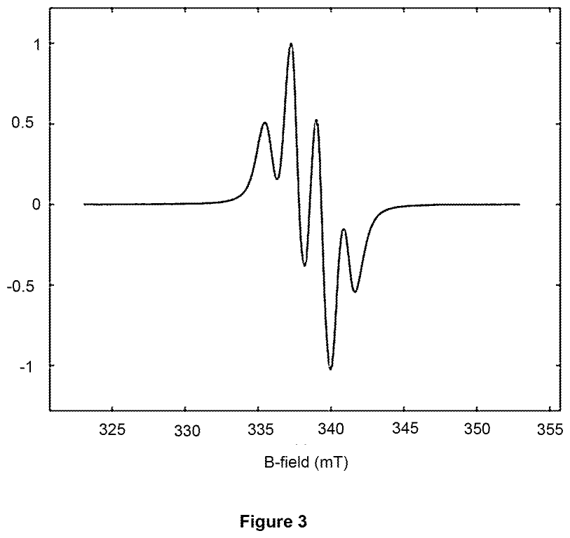

FIG. 3 displays an example of an X-band ESR spectrum measured at 77K in a photo-irradiated thin layer of pyruvic acid frozen onto a brass sample holder;

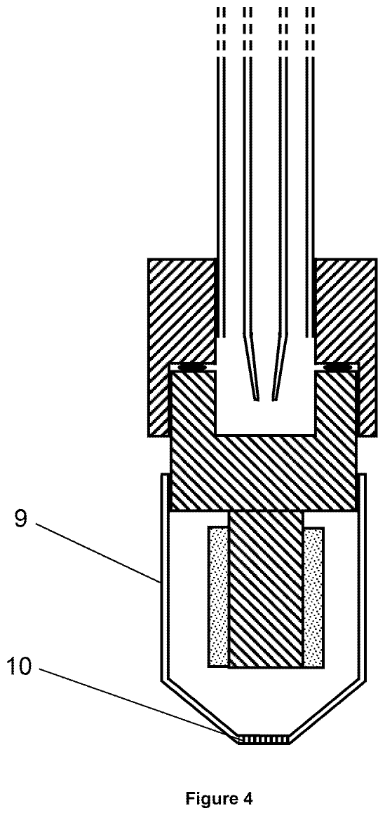

FIG. 4 illustrates the addition of a protective cap around the sample holder in a further embodiment of the invention;

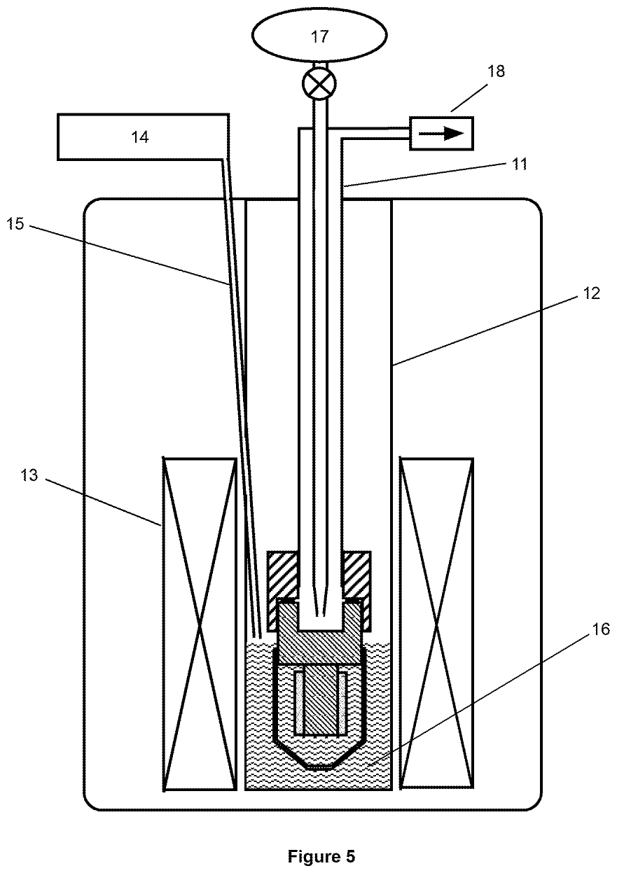

FIG. 5 illustrates how the sample holder of FIG. 4 can be placed inside a DNP apparatus;

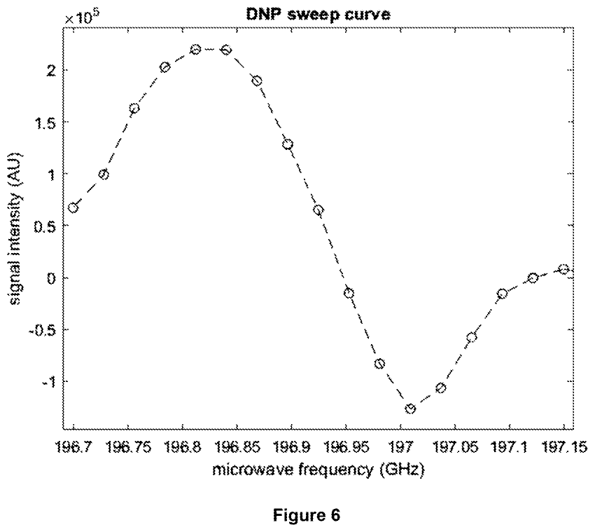

FIG. 6 shows a microwave sweep measured in a photo-irradiated thin layer of [1-¹³C]pyruvic acid frozen onto a copper sample holder that was inserted inside a 7 T/1.35K DNP apparatus;

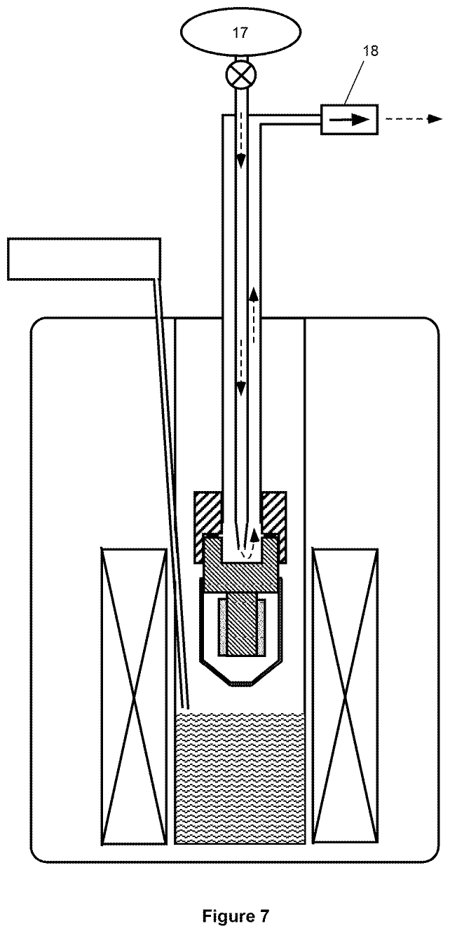

FIG. 7 illustrates how the photo-induced free radicals can be annihilated by warming up the sample holder of FIG. 4, connected to the heat exchanger using a warm fluid (gas) flowing through the thermal annihilation assembly;

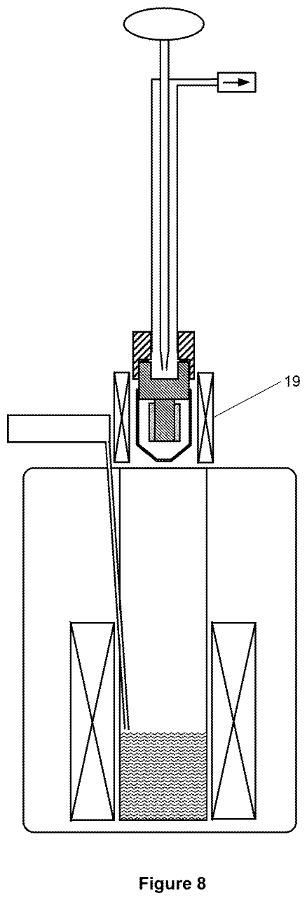

FIG. 8 illustrates how the sample holder can be extracted out of the DNP apparatus;

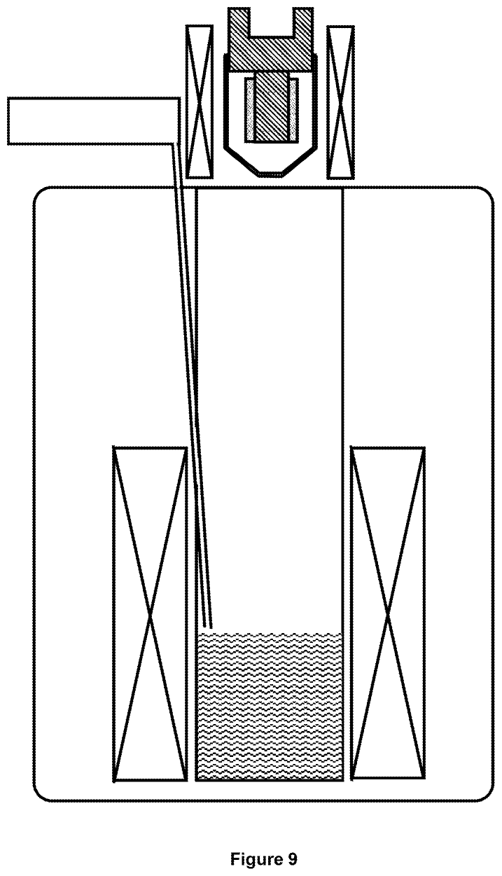

FIG. 9 illustrates how the thermal annihilation assembly of FIG. 8 can be disconnected from the heat exchanger once the sample holder has been extracted out of the DNP apparatus;

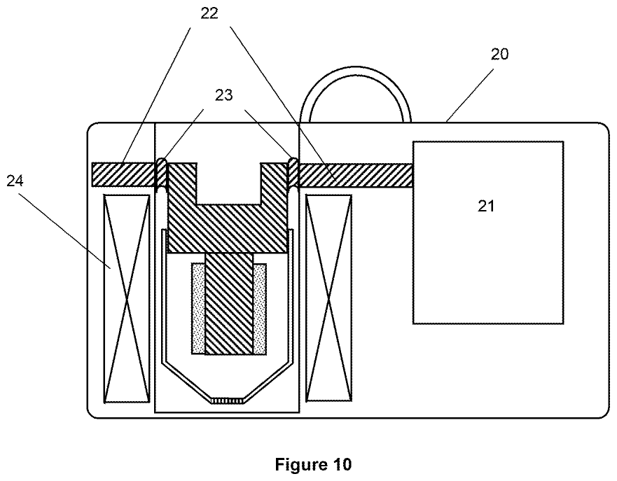

FIG. 10 is a cross section of a preferred embodiment of a transportable storage device;

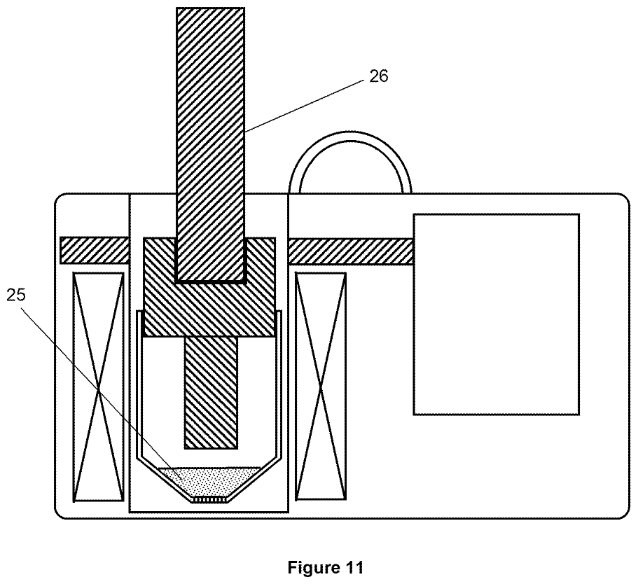

FIG. 11 illustrates how the frozen thin layer can be melted in the storage device of FIG. 10, using a heat source to obtain a solution containing molecules with HP spins; and

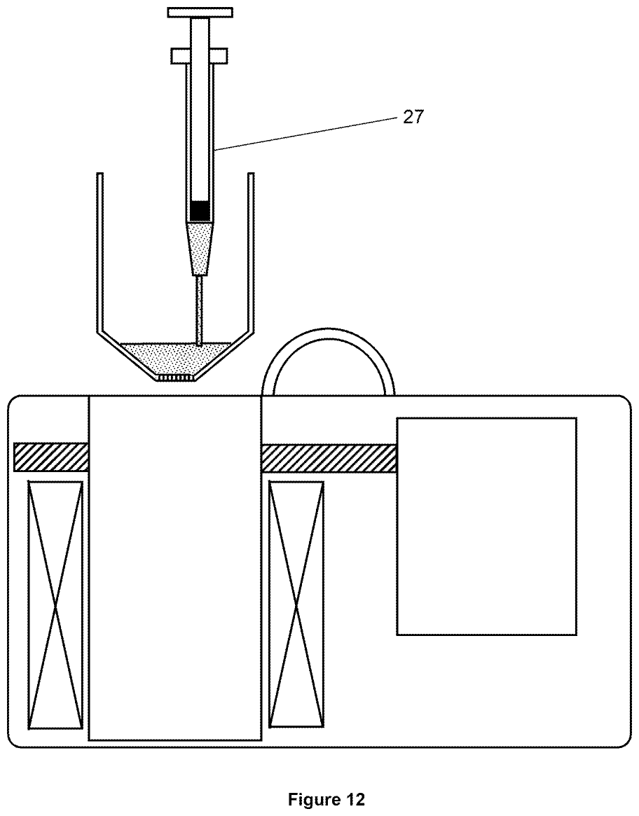

FIG. 12 illustrates how the solution of FIG. 11 can be collected to be eventually administrated to cells, animals, or humans.

In a first embodiment as shown in FIG. 1, a thermoconductive sample holder comprises a sample support, or sample supporting surface, (1) thermally connected to a heat exchanger (2). A thermometer can be thermally anchored to the sample holder (to the sample support or the heat exchanger or both) to monitor the temperature.

The sample support and the heat exchanger portions of the sample holder are fabricated from one or more highly thermally conductive materials, such as metals like copper, gold, or titanium, or alloys such as brass, or conductive non-metals such as sapphire. The sample support and the heat exchanger may be made as separate components and joined, or may be fabricated as a single component.

In the embodiment, the sample support is cylindrical, of 4.7 mm diameter and 40 mm length, and its cylindrical outer surface provides the sample support surface. The heat exchanger is also cylindrical, of diameter 9 mm, and is connected to an end of the sample support. A central portion of the opposite end of the heat exchanger, spaced from the sample support, is shaped to receive and couple to other components such as a cooling rod or a fluid heater assembly, and the outer periphery of the heat exchanger is shaped for insertion into a storage apparatus as described further below. The sample support and the heat exchanger in this embodiment are machined from a single piece of brass.

The heat exchanger is coupled to, and in thermal contact with, a cooling rod (3) which is in turn in thermal contact with a cold substance, e.g. dry ice or liquid nitrogen. A flow of heat from the sample holder to the cooling rod cools the sample holder to a temperature below 0 degree Celsius before the sample-support portion of the sample holder is put in direct contact with an initial, or starting, solution. The cooling rod also provides mechanical support for the sample holder, and allows convenient manipulation of the sample holder.

The starting solution contains one or more photo-reactive species (typically a keto-acid). If the photo-reactive species is not itself the molecule of interest, the starting solution also contains one or more molecules of interest. As the sample holder contacts the solution, a thin layer of frozen solution (4) is formed on the external support surface of the sample holder. The layer is sufficiently thin to allow rapid heat flow within the sample so that the whole of the sample can be maintained at substantially the same temperature as the sample holder. In the embodiment, the sample volume is 0.4 ml, with an external diameter of 5 mm, a thickness of 1.5 mm, and a height of 24 mm. More generally, the sample thickness may typically be between 1 micron and 5 mm, and the total volume between 10 microliter and 5 ml.

In the embodiment the sample is in the shape of a cylindrical shell. However, any convenient shape may be used, as long as the thickness of the sample is small enough to allow control of the temperature of the sample. For example the sample may be a flat or curved shape, although the cylindrical shell shape is preferred as it allows even irradiation of the sample to generate free radicals, and even exposure to microwaves during polarisation.

The sample holder is then removed from the cooling rod and coupled to a fluid heater assembly (7), sealed by a seal (8), without allowing the sample holder to rise above 0 C. As exemplified in FIG. 2, the sample is then exposed to UV and/or visible (UV-Vis) light (5) while being maintained cold (at a temperature in the range 40K to 200K) either by thermal conduction or by direct contact with a fluid, or by a combination of the two methods. If the temperature is controlled by thermal conduction, a fluid at a desired temperature is passed through the fluid heater assembly. If the temperature is controlled by direct contact between the sample and a fluid, then the sample support and the sample are preferably immersed in a cryogen such as liquid nitrogen (6).

The X-band ESR spectrum shown in FIG. 3 was measured at 77K in a photo-irradiated thin layer of pyruvic acid frozen onto a brass sample holder, using the approach illustrated in FIGS. 1 and 2, and confirms the presence of photo-irradiated free radicals inside the frozen thin layer.

As shown in FIG. 4, in a further embodiment of the invention a cap (9) is added around the sample support. At least a portion of the cap may include a porous wall (10), preferably with a pore size of 0.2 micron or less.

As depicted in FIG. 5, the fluid heater assembly (7) is then connected to a thermalisation insert (11) and the thermoconductive sample holder is inserted inside a DNP apparatus comprising a liquid helium cryostat (12), a superconducting magnet (13), and a microwave source (14) connected to a waveguide (15). The frozen thin layer of the sample can be either submerged in a liquid helium bath (16), if the cap contains a porous wall through which the helium can flow, or cooled by conduction through the thermoconductive sample holder, or cooled by a combination of these methods, to a temperature below 2K. DNP is then performed by applying microwaves, preferably frequency modulated, to the sample through the waveguide.

A microwave sweep measured in a photo-irradiated thin layer of [1-¹³C]pyruvic acid frozen on a copper sample holder using a 7 T/1.35K DNP apparatus is presented in FIG. 6. It demonstrates that the ¹³C spins in the frozen thin layer were efficiently polarized by DNP despite the presence of the sample holder. Therefore, handling the sample as a thin layer on the sample holder does not affect the irradiation or polarisation processes.

At the end of the DNP process, the sample is raised out of the liquid helium bath as shown in FIG. 7 and is rapidly warmed to a temperature between about 200K and 273K by flowing a fluid, preferably pressurised helium gas (17), through the leak-tight fluid heater assembly (7) of the thermalisation insert. The fluid flows through a one-way valve (18) in order to ensure that no inadvertent reversal of the flow occurs, which may affect the temperature of the sample holder and the sample. Feedback from the thermometer coupled to the sample holder is used to control the temperature and/or the flow rate of the fluid through the heater assembly, so that the temperature of the sample holder and the sample are accurately and rapidly controlled.

In another preferred embodiment (not illustrated) instead of connecting the sample holder to the fluid heater assembly, the sample holder may be supported on an insert comprising a supporting rod or tube and a resistive heater coupled to the heat exchanger. The insert is fabricated so as to minimize the heat load when it is connected to the sample holder; for example it may comprise a thin walled stainless steel tube. In this embodiment, the sample holder is supported on the insert during the UV-Vis irradiation and then during DNP, and the sample is cooled in each step by contact with the relevant cryogen (nitrogen for UV-Vis irradiation and helium for DNP). When DNP is complete and the sample holder is raised out of the liquid helium, an electrical current is applied through the resistive heater connected to the heat exchanger to rapidly raise the temperature of the sample. Feedback from the thermometer coupled to the sample holder is used to control the current applied to the resistive heater, so that the temperature of the sample holder and the sample are accurately and rapidly controlled. (In one embodiment, feedback from the thermometer is used in a calibration process, but may not be required in subsequent use of similar sample holders.)

Following this rapid thermalisation procedure, heated either by the fluid heater assembly or the resistive heater, the sample may be lowered back inside the liquid helium bath for storage. The sample can be stored in this way for some time, if desired, for example up to 48 hours.

As shown in FIG. 8, the sample can be extracted from the polarizer by lifting the thermoconductive sample holder out of the cryostat directly into a vessel with a second, separate magnetic field, preferably larger than 0.1 T, generated by a second magnet (19). The DNP apparatus and the second magnet are arranged so that the magnetic field along the sample path (usually the cryostat axis) does not decrease below a critical value of at least 10 mT, or preferably at least 0.1 T, at any point.

The thermalisation insert (either the fluid heater or the insert comprising the resistive heater) can then be disconnected from the heat exchanger as shown in FIG. 9.

In a further preferred embodiment shown in FIG. 10, the sample holder is placed in a transportable storage device (20) to store and transport the polarized sample. When positioned in the storage device, the sample is located within a third magnetic field within a third magnet (24), preferably a permanent magnet, and the heat-exchanger portion of the sample holder is thermally coupled to a thermoconductive cooling plate (21) by thermoconductive connections (23), which also provide mechanical support for the sample holder. The transportable storage device comprises a battery-operated cryocooler (21) to maintain the sample holder cold by heat flow through the thermoconductive cooling plate and thermoconductive connections. Feedback from the thermometer coupled to the sample holder may be used to control the cryocooler.

In an alternative embodiment, a cryogen such as liquid neon may be used to control the temperature of the sample holder in the storage device.

As the sample is transferred to the storage device, it is again important that the magnetic field along the sample path does not decrease below a critical value of at least 10 mT, or preferably at least 0.1 T, at any point.

In an alternative embodiment, the sample holder is raised from the cryostat after DNP directly into the transportable storage device. In that case, the third magnetic field substitutes for the second magnetic field in the description above.

The maximum storage time for the sample, while retaining its polarization, may depend on the materials in the sample, and on the processing and storage parameters, but the inventors' experiments suggest that storage times of 15 minutes, or an hour, or a day or even 48 hours may be achieved. This realises the possibility of generating a hyperpolarised sample in one location, and transporting it to another location for use in an MR technique. For example, the sample may be generated in one location and then transported in the storage device to a hospital. This presents a very significant advantage over conventional practice, in which the lifetime of a hyperpolarised sample may be only a minute, so that it needs to be prepared on site, in a hospital, where an MR technique is to be carried out.

FIG. 11 depicts the preparation of a liquid-state solution containing the hyperpolarised molecules of interest (25) for use in an MR technique. A heat source (26) is thermally coupled to the heat exchanger, and heat is supplied to the sample holder to rapidly melt the thin layer of the frozen sample within the third magnetic field. In another preferred embodiment, an external warm fluid such as water or helium gas is introduced to melt the sample.

As shown in FIG. 11, the liquid solution is conveniently collected in the cap (9) of the sample holder. As noted above, in the embodiment the volume of the solution is 0.4 ml, but in other applications it may typically be between 10 microliter and 5 ml.

The porous wall portion (10) of the cap has a porosity which allows cryogens, such as liquid helium during DNP, to pass through but which retains the liquid solution in the cap.

In a preferred embodiment depicted in FIG. 12, the melted solution is collected in a syringe (27) and possibly mixed with a solvent/buffer solution to obtain the target concentration of molecules of interest and a physiological pH. The solution can then be injected inside an NMR tube, a cell culture, a tissue, an animal, or a human prior to performing MR measurements. A suitable quality control (QC) procedure may be needed prior to injection into humans.

1. A method for preparing a hyperpolarised sample comprising the steps of:
forming a sample as a frozen layer of a solution on a surface of a thermoconductive sample holder, the solution comprising molecules for hyperpolarisation;
photo-inducing free radicals in the frozen layer by exposing it to radiation;
hyperpolarising the sample by dynamic nuclear polarization at a dynamic nuclear polarization temperature; and
raising the temperature of the sample to a thermalisation or quenching temperature by thermal conduction of heat through the sample holder, to quench the free radicals.

2. A method according to claim 1, in which the sample is in the form of a layer, of thickness preferably less than 5 mm, or 3 mm, or 2 mm or 1 mm.

3. A method according to claim 1, in which the thermoconductive sample holder comprises a heat exchanger, and the temperature of the sample is controlled by conduction of heat through the heat exchanger.

4. A method according to claim 3, in which the heat exchanger is cooled or heated by contacting the heat exchanger with a fluid flow of liquid or gas at a predetermined temperature.

5. A method according to claim 3, in which the heat exchanger is cooled or heated by thermal contact with an electrical cooler or an electrical heater.

6. A method according to claim 1, in which the sample holder comprises a thermometer, and the method comprises the step of using a feedback signal from the thermometer to control the temperature of the sample holder.

7. A method according to claim 1, further comprising the step of cooling the sample holder, by thermal conduction through the sample holder, to a frozen-sample-formation temperature for forming the frozen layer of the solution on the surface of the sample holder.

8. A method according to claim 1, further comprising the step of cooling the hyperpolarised sample by thermal conduction through the sample holder, after quenching the free radicals, for storage or transport.

9. A method according to claim 1, further comprising the step of holding the hyperpolarised sample at a storage temperature, for storage or transport, by thermal conduction through the sample holder.

10. A method according to claim 1, further comprising the step of raising the temperature of the hyperpolarised sample, by thermal conduction through the sample holder, to melt the sample, for example after storage for use in a magnetic resonance method.

11. A method according to claim 1, comprising the step of positioning a cap over the frozen sample and the thermoconductive sample holder, preferably prior to the dynamic nuclear polarization.

12. A method according to claim 11, comprising the step of melting the frozen sample prior to use, and collecting the melted sample in the cap.

13. An apparatus for handling a hyperpolarised sample, comprising a thermoconductive sample holder having a surface for, in use, carrying the sample in the form of a frozen layer, thermally couplable for the conduction of heat to and from a source of heat for controlling the temperature of the sample.

14. An apparatus according to claim 13, in which the sample holder comprises a heat exchanger for coupling the sample holder to the source of heat.

15. An apparatus according to claim 13, in which the source of heat comprises a flow of gas or liquid at a predetermined temperature.

16. An apparatus according to claim 13, in which the source of heat comprises an electrical cooler or an electrical heater.

17. An apparatus according to claim 13, in which the sample holder further comprises a thermometer, such as an electrical thermometer or thermocouple, for monitoring the temperature of the sample holder or the heat exchanger.

18. An apparatus according to claim 13, further comprising a cap positionable over the frozen sample (in use).

19. An apparatus according to claim 18, in which the cap is transparent to light in the ultraviolet and/or visible (UV-Vis) spectrum.

20. An apparatus according to claim 18, in which at least a portion of the cap includes a porous wall that is permeable to cryogens.

21. An apparatus according to claim 18, in which on the application of heat to the thermoconductive sample holder the sample, in use, can be melted and collected in the cap.

22. An apparatus according to claim 13, in which the sample holder can be positioned for exposure of the sample, in use, to radiation to form free radicals in the sample, is insertable into a polariser for dynamic nuclear polarisation of the sample, and is withdrawable from the polariser.

23. An apparatus according to claim 13, in which after the sample has undergone dynamic nuclear polarisation the sample holder is engageable with a storage apparatus in which the sample holder is couplable to a cooler and the sample, in use, can be held in a magnetic field.

24. A storage apparatus for receiving the apparatus of claim 13, comprising a cooling apparatus couplable to the thermoconductive sample holder and a magnetic field generator for applying a magnetic field to a frozen sample held, in use, by the thermoconductive sample holder.
